(19) United States
(12) Patent Application Publication
(10) Pub. No.: US 2004/0217794 A1
(43) Pub. Date: Nov. 4, 2004

(54) Propagation delay adjustment circuit

(76) Inventor: Mark Strysko, Mooresville, NC (US)

Correspondence Address: MORRISON & FOERSTER LLP, Attn: Douglas G. Hodder, 755 Page Mill Road, Palo Alto, CA, 94304, US

(21) Appl. No.: 10/427,557

(22) Filed: Apr. 30, 2003

(51) Int. Cl. H03H 11/26

(52) U.S. Cl. 327/263

(57) ABSTRACT

Disclosed is a method and apparatus for variably and independently delaying the rising and falling edges of a digital waveform including a dual polarity output buffer, a first delay circuit, a second delay circuit and a recombination circuit. The dual polarity output buffer outputs a first signal that is a substantial replica of the input signal and a second signal that is an inversion of the input signal. The first delay circuit is connected to the dual polarity output buffer and generates a first time delay in the rising edges of the first, non-inverted signal. The second delay circuit is also connected to the dual polarity output buffer and generates a second time delay in the rising edges of the second, inverted signal. The recombination circuit is connected to both the first delay circuit and the second delay circuit and combines the outputs thereof to generate a composite output signal representing the input signal with both the rising edges thereof and the falling edges thereof delayed independently.

### TECHNICAL FIELD

This invention relates to adjustment of delay in rising and falling edges in generated waveforms.

### BACKGROUND

In a number of electronics applications, it is desirable to generate or amplify a power signal in a relatively power efficient manner. For example, in applications having relatively tight space constraints, heat dissipation is typically undesirable. Accordingly, power loss in power signal generation or amplification, which can cause generation of excess heat, is generally avoided to the degree possible.

In such applications, it can be beneficial to use switch-mode output power stage topologies for power delivering devices such as power generators, amplifiers and supplies. Switch-mode topologies rely on the inherent efficiency of modulating a switch and can deliver relatively large amounts of power with relatively little loss (that is, they dissipate a relatively low amount of excess power).

One example of a switch-mode topology is shown in FIG. 1, which is a simplified schematic illustration of a “totem pole” output power stage 10. Output power stage 10 includes a first transistor 12 and a second transistor 14. Often, first and second transistors 12 and 14 are N-channel metal oxide semiconductor field effect transistors (“MOSFET”s). For the case in which transistors 12 and 14 are both N-channel MOSFETs, the drain of transistor 12 is connected to a supply voltage Vcc 16, the source of transistor 14 is tied to ground 18, and the source of transistor 12 is tied to the drain of transistor 14. Output 20 of output power stage 10 is taken where the source of transistor 12 is tied to the drain of transistor 14. A first control input 22 of output power stage 10 is tied to the gate of transistor 12 and a second control input 24 of output power stage 10 is tied to the gate of transistor 14. As shown, control inputs to output power stage 10 are a first and second digital waveform 26 and 28, respectively. First digital waveform 26 is applied to control input 22 and second digital waveform 28 is applied to control input 24.

In order to drive output power stage 10 properly, digital waveform 26 is 180 degrees out of phase with, in other words inverted from, digital waveform 28. In this way, transistors 12 and 14 are switched in unison, except out of phase. Specifically, when digital waveform 26 is high, digital waveform 28 is low and transistor 12 is on while transistor 14 is off. This places output 20 in a high state because it is connected by transistor 12 to Vcc. When digital waveform 26 is low, digital waveform 28 is high and output 20 is low because it is connected to ground through transistor 14. As shown, the signal at output 20 is a digital waveform. Output 20 can be placed through a low pass filter 30 to generate a low frequency output which can be varied by varying the duty cycle of (that is pulse width modulating) control signals 26 and 28. In this case, low pass filter 30 will have a cutoff frequency much below the modulating or carrier frequency of control signals 26 and 28. Additionally, if control signals 26 and 28 are digital waveforms with a fixed 50% duty cycle, the output of low pass filter 30 can approach a sine wave if the cutoff frequency of the filter is equal to or slightly above the carrier frequency of the control signals 26 and 28.

As explained above, during normal operation, transistors 12 and 14 are either on or off. When on, the current through the switch is relatively high and the voltage is relatively low. And, when off, the voltage is relatively high and the current is relatively low. In either state, there is relatively little power dissipation in generating an output signal.

It is important that transistors 12 and 14 be switched in unison and out of phase. This generally means that the control signals 26 and 28 of output power stage 10 shown in FIG. 1, be 180 degrees out of phase. Specifically, if, for example, a falling edge of control signal 26 occurs before the rising edge of control signal 28, rather than in unison with the falling edge, both transistors 12 and 14 are turned off for a period of time. This can result in distortion of the signal at output 20 and uncertainty about the level of the output of low pass filter 30. Further, and more significantly, if a rising edge occurs in control signal 28 before a falling edge occurs in control signal 26, Vcc will be essentially shorted to ground and both transistors 12 and 14 could be damaged or destroyed with a loss in efficiency. Additionally, these difficulties become more problematic with higher frequency control signals because fixed mismatches in rising and falling edges become a larger percentage of the period. Thus, relatively higher levels of distortion can be caused in an output waveform.

In switch-mode devices in general; such as amplifiers, power supplies and generators, there are typically two switching devices (such as transistors 12 and 14 of output power stage 10), which are designed to be switched in unison except out of phase. Accordingly, to avoid the problems described above, the precise 180 degree phase shift between the two control signals is important to maintain for switch-mode devices. However, this can be difficult to achieve in practice. If separate circuits are used to generate each control signal, the components generating the signals, even if matched, will likely generate different propagation delays and furthermore, the propagation delays for the rising and falling edges are likely to differ as well. Thus, the generated signals would not change state simultaneously.

In addition to switch-mode energy conversion applications, precise timing alignment of signals can also be necessary for the proper operation of some combinational logic and clocking applications. Accordingly, there is a need to be able to properly time align transitions of waveforms for many types of switch-mode devices in a relatively precise manner which includes independent controls of rising and falling edge delays. This need is particularly acute for higher frequency applications where problems due to mismatches in control signal transition alignment can be relatively severe.

### SUMMARY OF THE INVENTION

The present invention includes a method and apparatus for variably and independently delaying the rising and falling edges of digital waveforms. By driving the control inputs of a switch-mode device in accordance with the present invention, the rising and falling edges of the signals driving each control input can be precisely aligned in the presence of differing control circuit delays including differences between rising and falling edge delays. This can advantageously reduce difficulties, described above, which arise when there is a delay between the falling edge of a first control signal and the rising edge of the second control signal or when the rising edge of the second control signal precedes the falling edge of the first control signal.

A circuit for independently delaying both the rising edges and falling edges of a signal in accordance with the present invention includes a dual polarity output buffer which is a buffer with inverting and non-inverting outputs, a first delay circuit, a second delay circuit and a recombination circuit. The dual polarity output buffer outputs a first non-inverted signal that is a substantial replica of the input signal and a second signal that is an inversion of the input signal. The first delay circuit is connected to the dual polarity output buffer's non-inverting output and generates a first time delay in the rising edges of the first, non-inverted signal, which correlates to the rising edge of the input signal. The second delay circuit is connected to the dual polarity output buffer's inverting output and generates a time delay in the rising edges of the inverted signal, which correlates to the falling edges of the input signal. The recombination circuit is connected to both the first delay circuit and the second delay circuit and combines the outputs thereof to generate a composite output signal representing the input signal with both the rising edges thereof and the falling edges thereof delayed separately and independently.

In a method of generating a signal having an independently delay adjusted rising edge and falling edge with respect to an input signal in accordance with the present invention, the input signal is buffered to create a non-inverted and inverted version of the input signal. The rising edge of the input signal is then delayed by driving a first rising edge delay circuit with the non-inverted and buffered input signal. The falling edge of the input signal is also delayed by driving a second rising edge delay circuit with the inverted and buffered input signal. The outputs of the first rising edge delay circuit and second rising edge delay circuit are then combined to generate a composite signal representing the input signal with both the rising edges and the falling edges independently delayed.

### BRIEF DESCRIPTION OF THE DRAWINGS

FIG. 1 is a simplified schematic diagram of a “totem pole” output power stage for efficiently producing an output digital waveform by switching between two driving transistors.

FIG. 2 is a block diagram of a circuit for generating a digital waveform having variably delayed rising and falling edges in accordance with the present invention.

FIG. 3 is a schematic diagram illustrating a first embodiment of a circuit for generating a digital waveform having variably delayed rising and falling edges including a rising edge delay, a falling edge delay, and a recombination circuit in accordance with the present invention.

FIG. 4 is a timing diagram showing input, intermediate, and output signals of the rising edge delay shown in FIG. 3.

FIG. 5 is a timing diagram showing input, intermediate, and output signals of the recombination circuit shown in FIG. 3.

FIG. 6 is a schematic diagram illustrating an alternate embodiment of a rising edge delay for use in a propagation delay adjustment circuit in accordance with the present invention.

FIG. 7 is an illustration of intermediate and output waveforms generated by the rising edge delay circuit shown in FIG. 6.

FIG. 8 is a schematic diagram illustrating an alternate embodiment of the dual polarity output buffer for use in a propagation delay adjustment circuit in accordance with the present invention.

FIG. 8a is a schematic diagram illustrating yet another alternate embodiment of the dual polarity output buffer for used in a propagation delay adjustment circuit including a buffer on a feed-through line.

FIG. 9 is a schematic diagram illustrating an alternate embodiment of a rising edge delay circuit exhibiting linear delay versus control.

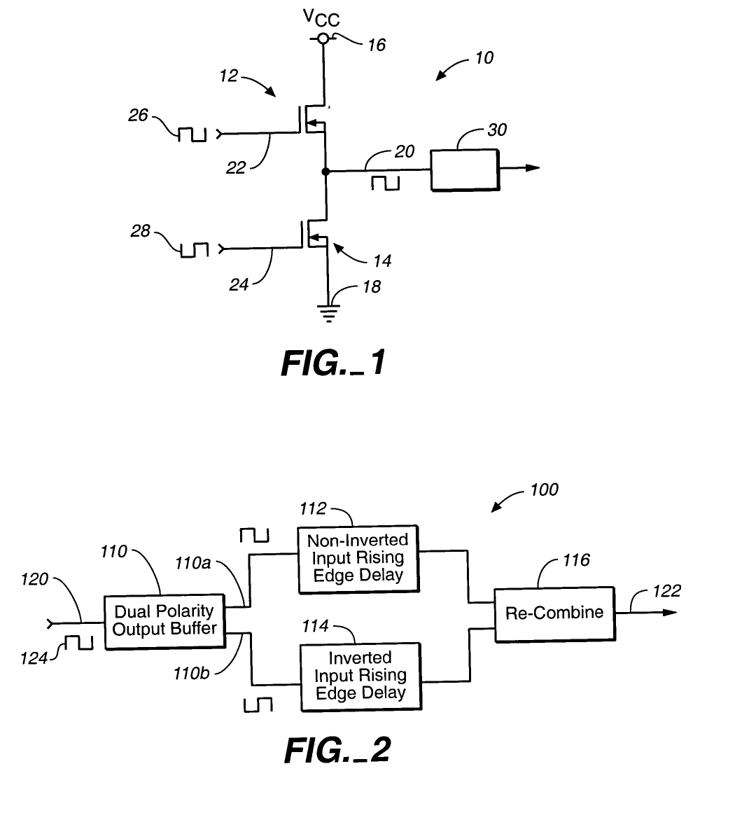

### DETAILED DESCRIPTION

The present invention includes a method and apparatus for variably and independently delaying the rising and falling edges of a digital waveform. As such, in driving the control inputs of a switch-mode device with a pair of digital waveforms in accordance with the present invention, the rising and falling edges of the signals driving each control input of the switch-mode device can be precisely time aligned.

FIG. 2 is a block diagram illustrating a method and apparatus for independently delaying both the rising and falling edge of a digital waveform in accordance with the present invention including propagation delay adjustment circuit 100. Propagation delay adjustment circuit 100 has input digital waveform 120 which feeds into a dual polarity output buffer 110. Dual polarity output buffer 110 preferably has a non-inverting output 110a and an inverting output 110b. The output of non-inverting output 110a is preferably a substantial replica of input digital waveform 124 with the added propagation delays of the buffer. The output of inverting output 110b is preferably an inversion of input digital waveform 124. Specifically, the output of inverting output 110b is preferably a digital waveform that is 180 degrees out of phase with input digital waveform 124 with the exception of the added propagation delays of the buffer.

Non-inverting output 110a is connected to the input of a non-inverted input rising edge delay 112 and inverting output 110b is connected to the input of an inverted input rising edge delay 114. Preferably, non-inverted input and inverted input rising edge delays 112 and 114 are substantial duplicates of each other. Both non-inverted input and inverted input rising edge delays 112 and 114 are for delaying the rising edge of a digital waveform provided at respective inputs. Preferably, as discussed in greater detail below, the amount of time retardation of the rising edge of a digital waveform provided by non-inverted input and inverted input rising edge delay 112 and 114 is variable and can be adjusted by the user. The output of both non-inverted input and inverted input rising edge delays 112 and 114 substantially match the inputs thereof, except that the rising edge of the respective output digital waveforms will be delayed, as further explained below, by anywhere from zero delay up until just before the falling edge occurrence of the input digital waveform. In the present application, the term “delay” can refer to both a finite delay and to zero or no delay.

Both the output of non-inverted input rising edge delay 112 and the output of inverted input rising edge delay 114 are fed into recombination circuit 116 which combines the two digital waveforms generated by the outputs of non-inverted input rising edge delay 112 and inverted input rising edge delay 114. The output of propagation delay adjustment 100 is output digital waveform 122 of recombination circuit 116. As further discussed below, recombination circuit 116 generates a digital waveform for which the timing of the rising edge is provided by the rising edge of the output of non-inverted input rising edge delay 112 and the timing of the falling edge is provided by the rising edge of the output of inverted input rising edge delay 114. Because rising edge delays 112 and 114 independently delay the rising edge of their respective input waveforms, the waveform at the output digital waveform 122 of recombination circuit 116 has both a rising edge and a falling edge which are delayed. And, the delay of the rising edge is independent of the delay of the falling edge; the delay of the rising edge of the output waveform at output digital waveform 122 being set by the delay provided by non-inverted input rising edge delay 112 and the delay of the falling edge being set by the rising edge delay provided by inverted input rising edge delay 114.

Because both the leading and trailing edges of an output digital waveform of propagation delay adjustment circuit 100 can be independently and variably delayed, a pair of propagation delay adjustment circuit such as propagation delay adjustment circuit 100 are well suited to provide the control waveforms for the two control inputs of a switch-mode device. Specifically, by adjusting delay in the rising and falling edges of each control input signal of a switch-mode device, the rising and falling edges of both control inputs can be precisely time-aligned. This can advantageously reduce distortion which can arise when there is mismatched delay between the falling edge of a first control waveform and the rising edge of the second control waveform. Relatively precise alignment of rising and falling edges of the inverted and non-inverted control waveforms can also advantageously reduce the likelihood of component or circuit damage and loss in efficiency, which can result when the rising edge of the second control waveform precedes the falling edge of the first control waveform.

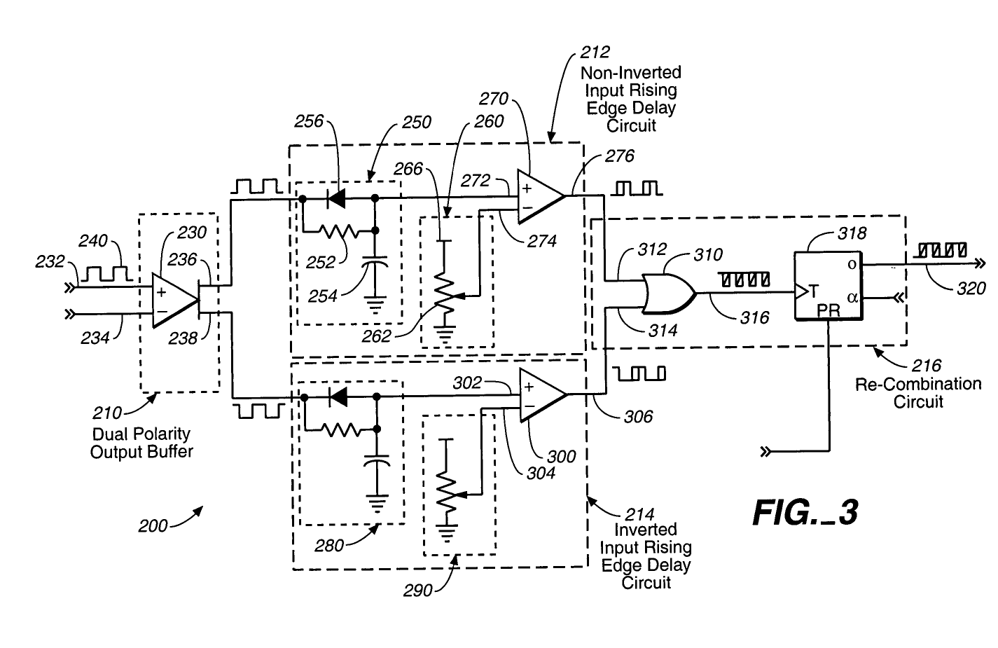

FIG. 3 is a schematic diagram illustrating a first embodiment of a propagation delay adjustment circuit 200 for independently delaying both the rising and falling edge of a digital waveform in accordance with the present invention. Propagation delay adjustment circuit 200 includes dual polarity output buffer 210, non-inverted input rising edge delay circuit 212, inverted input rising edge delay circuit 214 and recombination circuit 216. Dual polarity output buffer 210, non-inverted input rising edge delay circuit 212, inverted input rising edge delay circuit 214 and recombination circuit 216 each respectively have the function, discussed above, of dual polarity output buffer 110, non-inverted input rising edge delay 112, non-inverted input rising edge delay 114 and recombination 116 shown in FIG. 2.

Dual polarity output buffer 210 preferably includes a differential comparator 230, which acts as a buffer for an input digital waveform and generates two outputs; a first output is a substantial replica of the input waveform and a second output is a substantial inversion of the input waveform. Configuration and operation of a differential comparator such as differential comparator 230 is well understood by those skilled in the art. Differential comparator 230 preferably includes buffer input 232 and logic threshold reference input 234. Buffer input 232 preferably carries input digital waveform 240 which is to have a delay introduced into both its rising and trailing edges by propagation delay adjustment circuit 200. Logic threshold reference input 234 preferably carries nominal logic threshold of input digital waveform 240. Differential comparator 230 also includes non-inverting output 236 and buffer inverting output 238. Because the reference input carries the nominal logic threshold of the input waveform, non-inverting output 236 will transition to a high state whenever input digital waveform 240 transitions to a high state and will transition to a low state whenever input digital waveform 240 transitions to a low state. As such, the digital waveform on non-inverting output 236 will be a substantial replica of input digital waveform 240. Buffer inverting output 238 carries an output digital waveform which is inverted from the waveform on buffer non-inverting output 236 (that is, a digital waveform which is 180 degrees out of phase with the digital waveform on buffer non-inverting output 236). Typically, there will be some propagation delay associated with differential comparator 230. This will likely cause a slight shift in time between input digital waveform 240 and the output waveform on non-inverting output 236. However, because the inverted input waveform on buffer inverting output 238 is also generated by differential comparator 230 from input digital waveform 240, it will experience approximately the same slight time shift (in addition to the 180 degree phase shift) from the input digital waveform 240 caused by propagation delay associated with differential comparator 230. As such, the non-inverted output waveform on non-inverting output 236 will be substantially 180 degrees out of phase with the inverted output waveform on buffer inverting output 238. If this is not the case, any differential time shift in the buffer outputs can be adjusted out by the propagation delay adjustment circuit 200.

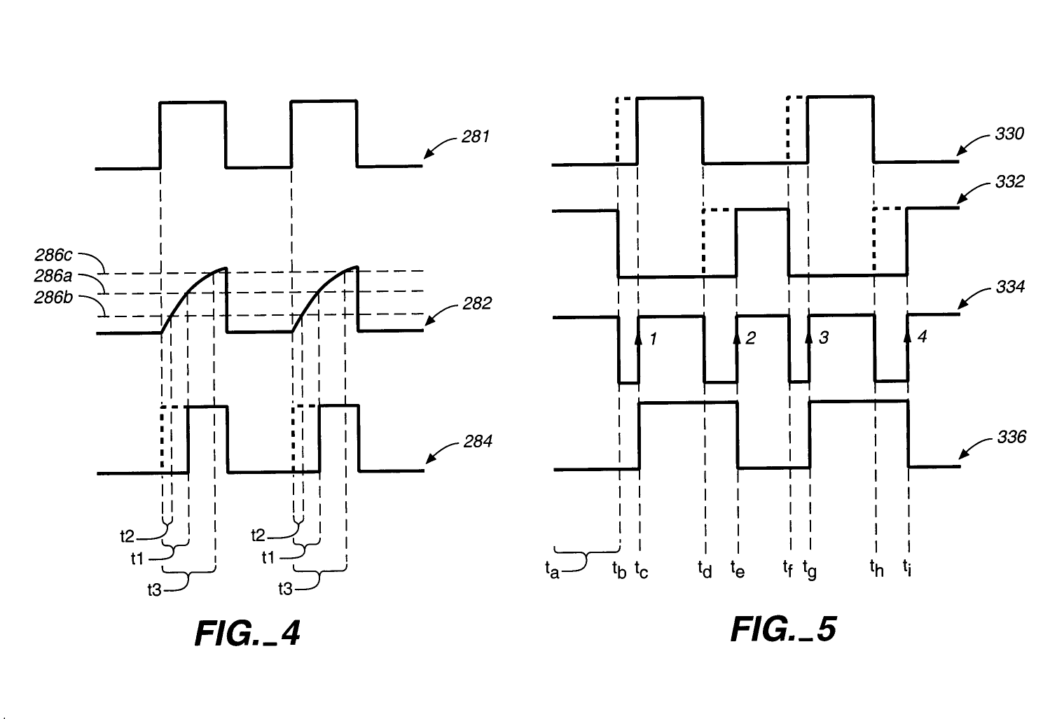

The waveform on buffer non-inverting output 236 is fed into non-inverted input rising edge delay circuit 212. Non-inverted input rising edge delay circuit 212 preferably includes non-inverted input RCD-circuit (Resistor Capacitor Diode) 250, non-inverted input potentiometer 260, and comparator 270, each of which will be explained in greater detail below. FIG. 4 is an illustration of the effect of non-inverted input rising edge delay circuit 212 on the input digital waveform from non-inverted output 236 of differential comparator 230. In FIG. 4, rising edge delay circuit input waveform 281 illustrates the input to non-inverted input rising edge delay 212, RCD-circuit output waveform 282 illustrates the output of non-inverted input RCD-circuit 250, and rising edge delay circuit output waveform 284 illustrates the output of non-inverted input rising edge delay circuit 212.

Non-inverted input RCD-circuit 250 preferably includes resistor 252 and diode 256 connected in parallel between the non-inverting output of dual polarity output buffer 210 and a non-inverted 272 of input comparator 270. The cathode of diode 256 is connected to the non-inverting output of dual polarity output buffer 210 and the anode is connected to the non-inverted input 272 of comparator 270. Non-inverted input RCD-circuit 250 also preferably includes capacitor 254 connected from the non-inverting input 272 of comparator 270 to ground. When rising edge delay circuit input waveform 281 transitions from low to high, diode 256 is back biased and capacitor 254 charges at a logarithmic time constant dictated by the product of the resistance of resistor 252 and the capacitance of capacitor 254. This capacitor charging is the logarithmic rise of RCD-circuit output waveform 282. When rising edge delay circuit input waveform 281 transitions from high to low, diode 256 is forward biased, rapidly discharging capacitor 254 through the low impedance path of diode 256. This falling transition of RCD-circuit output waveform 282 is a substantial replica of the falling edge of rising edge delay circuit input waveform 281. RCD-circuit output waveform 282 is then presented to input 272 of non-inverted input comparator 270.

Comparator 270 also includes reference input 274 that is connected to the output of non-inverted input potentiometer 260. Potentiometer supply voltage 266 preferably, but not necessarily, provides a voltage at the maximum high logic level of buffer non-inverting output 236. As is well understood by those skilled in the art, the output of non-inverted input potentiometer 260 is a dc signal variable between ground and the potentiometer supply voltage 266 by adjustment. This dc signal is provided to reference input 274 of non-inverted input comparator 270.

Non-inverted input comparator 270 compares the two voltages on inputs 272 and 274, generates a high logic level when input 272 is at a higher voltage than reference input 274, and generates a low logic level output when the voltage level of input 272 is lower than the voltage level at reference input 274. Accordingly, as the logarithmically rising edge of RCD-circuit output waveform 282 shown in FIG. 4 is presented to input 272, the output 276 of non-inverted input comparator 270, as shown by rising edge delay circuit output waveform 284, will remain low until the rising edge of input RCD-circuit output waveform 282 exceeds the dc level of reference input 274, shown by phantom line 286a. At this point, as shown by rising edge delay circuit output waveform 284, output 276 of non-inverted input comparator 270 will go high. In this way, output 276 of non-inverted input comparator 270 generates the rising edge of rising edge delay circuit output waveform 284 which is delayed by delay time t1 referenced to the rising edge of rising edge delay circuit input waveform 281 .

If the voltage level of reference input 274 is set at a relatively lower level, as shown, for example, by phantom line 286b, then the rising edge of RCD-circuit output waveform 282 on input 272 of non-inverted input comparator 270 will rise above the dc signal level on reference input 274 of non-inverted input comparator 270 in a relatively shorter time. As such, the delay of the rising edge of output rising edge delay circuit output waveform 284 on output 276 of non-inverted input comparator 270, as shown by delay time t2, is relatively shorter than if a relatively higher voltage level is set on reference input 274. In the same way, setting the voltage of input 274 at a relatively higher level, as shown by phantom line 286c, leads to a relatively longer delay time t3. It is to be understood that the voltage level at reference input 274 of non-inverted input comparator 270 need not be set by a potentiometer such as non-inverted input potentiometer 260. It is considered that this voltage be set by any device which provides a constant output voltage and can preferably be adjusted by a user.

As noted above, the falling edge of rising edge delay circuit input waveform 281 provided to the input of non-inverted input rising edge delay circuit 212 is not substantially effected by non-inverted input RCD-circuit 250. Additionally, the voltage of the wiper of potentiometer 262 is preferably always set above the low level of input rising edge delay circuit input waveform 281. As such, the falling edge of rising edge delay circuit input waveform 281 will be passed through non-inverted input comparator 270 substantially without any delay because after the falling edge of rising edge delay circuit input waveform 281 drops to low level, the voltage level of input 272 will always be below the voltage level of reference input 274. As such, non-inverted input rising edge delay circuit 212 does not substantially effect the timing or shape of the falling edge of an input signal.

Therefore, as described above, by adjusting non-inverted input potentiometer 260, the rising edge of an input signal provided to non-inverted input rising edge delay circuit 212 can be adjustably delayed without substantially effecting the timing or shape of the falling edge of the input waveform. The amount of rising edge delay, which can be introduced into a waveform, is limited by the time from rising edge to falling edge. Thus, the amount of delay introduced can be varied from zero delay up to approximately the time from rising edge to falling edge of the input waveform into non-inverted input rising edge delay circuit 212.

Propagation delay adjustment circuit 200 also includes inverted input rising edge delay circuit 214 which preferably includes the same components in the same configuration as non-inverted input rising edge delay circuit 212. Specifically, inverted input rising edge delay circuit 214 includes: inverted input RCD-circuit 280 which preferably includes the same components in the same configuration as non-inverted input RCD-circuit 250; inverted input potentiometer 290 which preferably includes the same components in the same configuration as non-inverted input potentiometer 260; and inverted input comparator 300 which operates in the same way as non-inverted input comparator 270. Buffer inverting output 238 of dual polarity output buffer 210 is connected to the input of inverted input rising edge delay circuit 214. The output of inverted input RCD-circuit 280 is connected to input 302 of inverted input comparator 300 and the output of inverted input potentiometer 290 is connected to reference input 304 of inverted input comparator 300 to provide a variable voltage to reference input 304.

Because inverted input rising edge delay circuit 214 is preferably a substantial replica of non-inverted input rising edge delay circuit 212, inverted input rising edge delay circuit 214 operates in the same way as non-inverted input rising edge delay circuit 212 to generate a user adjustable delay in the rising edge of a waveform generated by the inverting output of dual polarity output buffer 210. A waveform having such a delayed rising edge is generated at output 306 of inverted input rising edge delay circuit 214. However, since the rising edge of buffer inverting output 238 of dual polarity output buffer 210 corresponds to the falling edge of input digital waveform 240, the delay generated by inverted input rising edge delay circuit 214 corresponds to a delay of the falling edge of input digital waveform 240.

Output 276 from non-inverted input rising edge delay circuit 212 and output 306 from inverted input rising edge delay circuit 214 are provided to inputs of recombination circuit 216. Recombination circuit 216 preferably includes logic OR gate 310 and toggle flip-flop 318. Output 276 of non-inverted input rising edge delay circuit 212 is preferably connected to a first input 312 of OR gate 310 and output 306 of inverted input rising edge delay circuit 214 is preferably connected to a second input 314 of OR gate 310. OR gate 310 serves to combine the output signals from non-inverted input rising edge delay circuit 212 and inverted input rising edge delay circuit 214.

FIG. 5 is a timing diagram illustrating the operation of the recombination circuit 216 including OR gate 310 and toggle flip-flop 318. In FIG. 5, signal 330 represents the output of non-inverted input rising edge delay circuit 212 provided to first input 312 of OR gate 310. Waveform 332 represents the output of inverted input rising edge delay circuit 214 provided to second input 314 of OR gate 310. Waveform 334 represents the waveform at the output 316 of OR gate 310. Waveform 336 represents the waveform on output 320 of toggle flip-flop 318, which is preferably the desired output of propagation delay adjustment circuit 200.

The operation of recombination circuit 216 will now be explained. OR gate 310 functions as a half-adder without a carry input or output. Ordinarily OR gate 310 would need to be an XOR (Exclusive-OR) gate to perform this function. However, the way the input signals to OR gate 310 are generated, guarantees mutual exclusivity so that only an OR gate is required. Specifically, OR gate 310 generates the waveform 334, which is the waveform at the output 316 of OR gate 310. Waveform 334 is characterized by a normally high digital waveform with a first falling edge corresponding to the original input digital waveform 240 rising edge followed by a first rising edge corresponding to the rising edge of the output from non-inverted input rising edge delay circuit 212 that corresponds to the desired timing of the final output, toggle flip-flop output waveform 336, rising edge. The low time between the first falling and rising edges of waveform 332 represents the introduced time delay to the original input digital waveform 240 rising edge. Following the first rising edge corresponding to the output from non-inverted input rising edge delay circuit 212 is a second falling edge corresponding to the original input digital waveform 240 falling edge followed by a second rising edge corresponding to the rising edge of the output from inverted input rising edge delay circuit 214 that corresponds to the desired timing of the final output, toggle flip-flop output waveform 336, falling edge. The low time between the second falling and rising edges of this waveform represent the introduced time delay to the original input digital waveform 240 falling edge.

Toggle flip-flop 318 is positive-edge triggered and operates on OR gate 310 output waveform 334 as a frequency divide-by-two function. Toggle flip-flop 318 changes output 320 state, output waveform 336, on every rising edge transition at its input, OR gate 310 output waveform 334. These rising edge transitions are shown as arrows and marked by the numbers 1, 2, 3 and 4 on OR gate 310 output waveform 334 of FIG. 5. Toggle flip-flop 318 starting output level of the output waveform 336 is reset to a low level by the ‘reset’ input 322 of flip-flop 318. If an inverted polarity output is desired, the set input of flip-flop 318 can be used. A power-on-reset circuit will normally control the ‘reset’ or ‘set’ inputs to the flip-flop 318 upon circuit power being applied. Significant, equal time dotted lines are shown in FIG. 5 and have the following time associations.

tₐ The starting time, indicating the starting state of all waveforms.

t_{b} The first rising edge of the input digital waveform 240 to propagation delay adjustment circuit 200.

The first rising edge of buffer input 232.

The first rising edge of buffer non-inverting output 236.

The first rising edge of non-inverted input rising edge delay circuit 212, to be delayed.

The first falling edge of buffer inverting output 238.

The first falling edge of inverted input rising edge delay circuit 214 to be unchanged.

The first falling edge of inverted input comparator output 306.

The first falling edge of second OR gate input 314 as waveform 332.

t_{c} The first delayed rising edge of non-inverted input rising edge delay circuit 212.

The first rising edge of non-inverted input comparator output 300.

The first rising edge of first OR gate input 312 as waveform 330.

The first rising edge of OR gate output 316 as indicated in waveform 334 by the rising edge arrow 1.

The first rising edge of toggle flip-flop output 320 as indicated in waveform 336.

t_{d} The first falling edge of the input digital waveform 240 to propagation delay adjustment circuit 200.

The first falling edge of buffer input 232.

The first rising edge of buffer inverting output 238.

The first rising edge of inverted input rising edge delay circuit 214, to be delayed.

The first falling edge of buffer non-inverting output 236.

The first falling edge of non-inverted input rising edge delay circuit 212, to be unchanged.

The first falling edge of non-inverted input comparator output 276.

The first falling edge of first OR gate input 312 as waveform 330.

tₑ The first delayed rising edge of inverted input rising edge delay circuit 214.

The first rising edge of inverted input comparator output 306.

The first rising edge of second OR gate input 314 as waveform 332.

The first falling edge of OR gate output 316 as indicated in waveform 334 by the rising edge arrow 2.

The first falling edge of toggle flip-flop output 320 as indicated in waveform 336.

t_{f} The second rising edge of the input digital waveform 240 to propagation delay adjustment circuit 200.

The second rising edge of buffer input 232.

The second rising edge of buffer non-inverting output 236.

The second rising edge of non-inverted input rising edge delay circuit 212, to be delayed.

The second falling edge of buffer inverting output 238.

The second falling edge of inverted input rising edge delay circuit 214, to be unchanged.

The second falling edge of inverted input comparator output 306.

The second falling edge of second OR gate input 314 as waveform 332.

t_{g} The second delayed rising edge of non-inverted input rising edge delay circuit 212.

The second rising edge of non-inverted input comparator output 300.

The first second edge of first OR gate input 312 as waveform 330.

The first second edge of OR gate output 316 as indicated in waveform 334 by the rising edge arrow 3.

The second rising edge of toggle flip-flop output 320 as indicated in waveform 336.

tₕ The second falling edge of the input digital waveform 240 to propagation delay adjustment circuit 200.

The second falling edge of buffer input 232.

The second rising edge of buffer inverting output 238.

The second rising edge of inverted input rising edge delay circuit 214, to be delayed.

The second falling edge of buffer non-inverting output 236.

The second falling edge of non-inverted input rising edge delay circuit 212 to be unchanged.

The second falling edge of non-inverted input comparator output 276.

The second falling edge of first OR gate input 312 as waveform 330.

tᵢ The second delayed rising edge of inverted input rising edge delay circuit 214.

The second rising edge of inverted input comparator output 306.

The second rising edge of second OR gate input 314 as waveform 332.

The second falling edge of OR gate output 316 as indicated in waveform 334 by the rising edge arrow 4.

The second faling edge of toggle flip-flop output 320 as indicated in waveform 336.

The output of toggle flip-glop 318 is also the output of propagation delay adjustment circuit 200 and is shown if FIG. 5 as digital waveform 336. The first rising edge of waveform 336 corresponds to the desired delayed first rising edge of the input digital waveform 240 to propagation delay adjustment circuit 200. The first falling edge of waveform 336 corresponds to the desired delayed first falling edge of the input digital waveform 240. The second rising edge of waveform 336 corresponds to the desired delayed second rising edge of the input digital waveform 240. The second falling edge of waveform 336 corresponds to the desired delayed second falling edge of the input digital waveform 240. Propagation delay adjustment circuit 200 output waveform 336 therefore is a duplicate of the propagation delay adjustment circuit 200 input waveform 240 with the rising and falling edges independently delayed.

As pointed out earlier and referring to digital waveform 334 of FIG. 5 corresponding to the output of OR gate 310 and the input to toggle flip-flop 318, the low time between the first falling and rising edges of waveform 334 represents the introduced time delay to the original input digital waveform 240 rising edge. The low time between the second falling and rising edges of waveform 334 represents the introduced time delay to the original input digital waveform 240 falling edge. As these delays approach zero, these low times are very short. Therefore, a limitation to this circuit is that delays must be larger than gate rise, fall and setup times or toggle flip-flop 318 will not be able to change states. This limitation can be alleviated by making sure there is a fixed common mode quiescent delay for the rising edge delay and the falling edge delay. This technique is used to create apparent dual polarity time delays between two sets of delay adjustment circuits. This is achieved by first starting out by centering the delay controls quiescently in the center of their adjustment range and then holding one delay control channel constant while adjusting the other symmetrically about the quiescent point. If more adjustment range is required for one polarity, the quiescent point can be shifted appropriately. The quiescent channel can also be substituted with a delay line set to the equivalent desired quiescent delay value.

As mentioned previously, the other limitation to the circuit is that the rising edge delay must be less than the input waveform high-level pulse width, because the falling edge of the output cannot occur before the rising edge of the input. Likewise, the falling edge delay must be less than the low-level pulse width. If this is not observed, pulses will be dropped and the output may invert. This limitation is not normally an issue for most applications as the relative delays between rising and falling edges are usually much less than the minimum pulse widths of the signals.

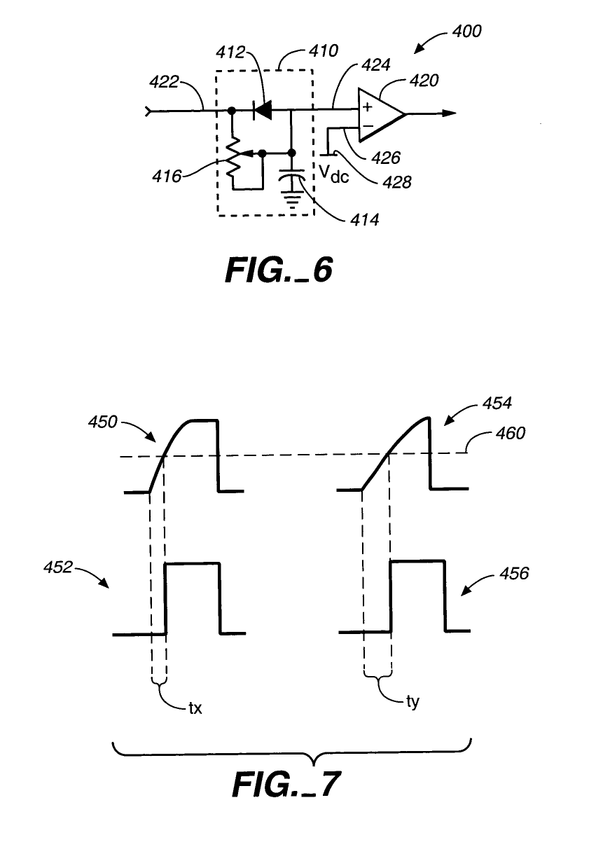

FIG. 6 is a schematic diagram illustrating an alternate embodiment of a rising edge delay in accordance with the present invention. As non-inverted input rising edge delay circuit 212 and inverted input rising edge delay circuit 214, delay circuit 400 illustrated in FIG. 6 acts to delay the leading edge of a digital waveform provided at input 422. Like non-inverted input rising edge delay circuit 212 and inverted input rising edge delay circuit 214, delay circuit 400 includes an RC circuit 410 and a comparator 420. However, RC circuit 410, which includes capacitor 414 and diode 412, includes a variable resistor 416, rather than a fixed resistor. In this way, the RC time constant of RC circuit 410, and thereby the time required for the rising edge of an input signal to reach a predetermined fixed voltage, can be varied by varying the resistance of variable resistor 416. As with first RC circuit 250, a diode 412 provides a low impedance path through RC circuit 410 for the falling edge of an input signal. As such, the falling edge of an input signal is not substantially effected by RC circuit 410.

The output of RC circuit is provided to a non-inverting input 424 of comparator 420. A inverting input 426 of comparator 420 is held at a constant de voltage provided by voltage source 428. Voltage source 428 can be any source that can provide a constant dc voltage to input 426 of comparator 420.

The output of comparator 420 preferably goes high when the voltage level of non-inverting input 424 rises above the voltage level of inverting input 426. FIG. 7 illustrates input and output waveforms for two values of variable resistor 416. A first value is shown by input waveform 450 and output waveform 452. As shown, the output of RC circuit 410 is a waveform having a non-linear rising leading edge and a substantially “square” falling edge. If the value of variable resistor 416 is set relatively low, the rise time for the leading edge of waveform 450 will be relatively fast. As such, the voltage level on input 424 will reach the constant dc level 460 relatively quickly. And, as shown by output waveform 452, the delay tₓ of the rising edge of the output of delay circuit 400 will be relatively short. Input waveform 454 illustrates the signal on non-inverting input 424 of comparator 420 when variable resistor 416 is set to a relatively higher value. At such a relatively higher resistance, the rise time for the leading edge of waveform 454 will be relatively longer and, thus, it will take a relatively longer period of time for the voltage level of input 424 to reach the constant dc voltage level 460 on input 426. As such, as shown by output waveform 456, the delay t_{y} of the rising edge of the output of delay circuit will be relatively longer. A delay circuit such as delay circuit 400 can also be used in place of inverted input rising edge delay circuit 214 shown in FIG. 3.

FIG. 9 is a schematic diagram illustrating an alternate embodiment of a rising edge delay circuit in accordance with the present invention with a linear delay versus control. Transistor 510 represents the output transistor of an open drain device such as a comparator, buffer or inverter. Current source 520 provides a constant or variable current source depending on the application. Comparator 540 compares the capacitor 530 voltage to the reference voltage 550. The reference voltage 550 can be either constant or variable depending on the application. There are two basic ways in which this circuit can be used.

The first method uses the current source 520 as a variable current source and the reference voltage 550 as a constant voltage. On the rising edge of input 570, the transistor 510 turns off and the voltage on capacitor 530 begins to rise in a linear ramp. The capacitor voltage 560 ramp begins at a zero voltage left from when the transistor 510 was on, shorting the current source to ground, just before the input 570 transitioned from low to high. The output 580 transitions from low to high when the ramping capacitor voltage 560 exceeds the reference voltage 550. If the current source is set small, the capacitor voltage 560 will ramp at a slower rate and take longer to exceed the reference voltage 550. This will create a longer delay. If the current source is set larger, the capacitor voltage 560 will ramp at a faster rate and take a shorter time to exceed the reference voltage 550. This will create a shorter delay.

The second method uses the current source 520 as a fixed current source and the reference voltage 550 as a variable voltage. On the rising edge of input 570, the transistor 510 turns off and the voltage on capacitor 530 begins to rise in a linear ramp. Capacitor voltage 560 ramp begins at a zero voltage left from when transistor 510 was on, shorting the current source to ground, just before input 570 transitioned from low to high. Output 580 transitions from low to high when the ramping capacitor voltage 560 exceeds the reference voltage 550. If the reference voltage 550 is set reduced, the capacitor voltage 560 will not take as long to ramp and exceed the reference voltage 550. This will create a shorter delay. If the reference voltage 550 is set increased, the capacitor voltage 560 will take longer to ramp and exceed the reference voltage 550. This will create a longer delay.

The foregoing descriptions of specific embodiments of the present invention have been presented for purposes of illustration and description. They are not intended to be exhaustive or to limit the invention to the precise forms disclosed, and it should be understood that many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. Many other variations are also to be considered within the scope of the present invention.

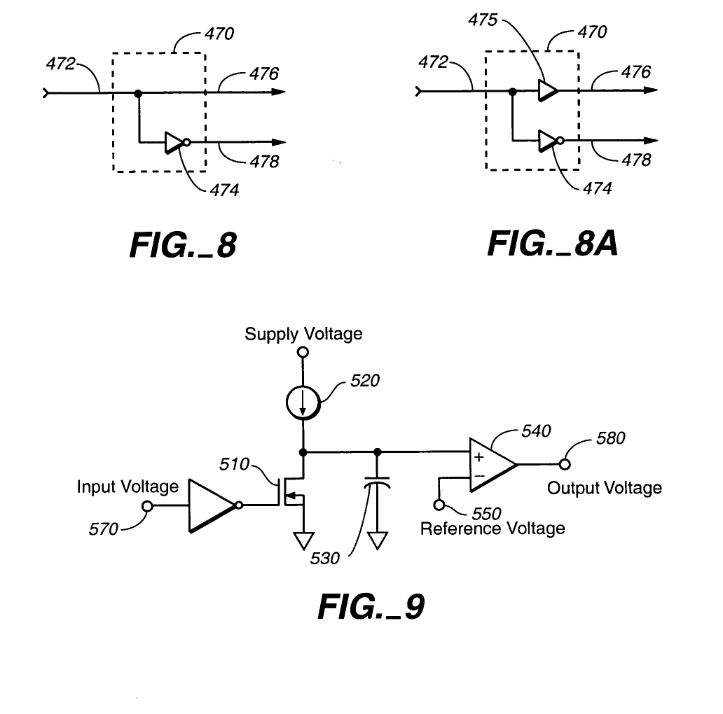

As a first example, it is to be understood that a dual polarity output buffer 110 can be any device or combination of devices that can generate an inverted and non-inverted signal from an input signal. For example, FIG. 8 is a schematic diagram of another embodiment of a dual polarity output buffer 470 in accordance with the present invention. Dual polarity output buffer 470 includes signal input 472, a non-inverting output 476 and an inverting output 478. Non-inverting output 476 can simply be a feed through of the input signal from input 472 or a non-inverting buffer 475 as shown in FIG. 8a. An inverter 474 is placed in series to input 472 and inverting output 478 is the output of inverter 474. Thus, non-inverting output 476 generates a replica of an input signal and inverting output 478 generates a signal, which is an inversion of the input signal. All components are logic gates.

As a second example, though the present invention has been presented as being advantageous for driving the control inputs of a switch-mode device, an apparatus and method, in accordance with the present invention, may be used for any application in which it is desirable to be able to independently delay the rising and falling edges of a digital waveform. One example may be to time synchronize multiple clocking signals. Another example may be to adjust the duty cycle of a duty cycle critical waveform.

What is claimed is:

1. A circuit arrangement for delaying both a rising edge and a falling edge of an input signal including:
a dual polarity output buffer for generating a first signal and a second signal, the first signal being a substantial replica of the input signal and the second signal being a substantial inversion of the input signal;
a first delay circuit interconnected to the dual polarity output buffer for causing a first time delay in the rising edge of the first signal;
a second delay circuit interconnected to the dual polarity output buffer for causing a second time delay in the rising edge of the second signal; and
a recombination circuit interconnected to both the first delay circuit and the second delay circuit and which combines an output of the first delay circuit and an output of the second delay circuit to generate a composite output signal representing the input signal with both the rising edge thereof and the falling edge thereof delayed.

2. The circuit arrangement of claim 1 wherein the input signal is a digital waveform.

3. The circuit arrangement of claim 1 wherein the delay in the rising edge of the composite output signal can be varied independently from the delay in the falling edge of the composite output signal.

4. The circuit arrangement of claim 1 wherein the dual polarity output buffer includes a circuit input, and the first delay circuit includes a first delay input which is connected to the circuit input.

5. The circuit arrangement of claim 1 wherein the dual polarity output buffer includes a first comparator having a non-inverting output and an inverting output wherein the non-inverting output is connected to the first delay circuit and the inverting output is connected to the second delay circuit.

6. The circuit arrangement of claim 1 wherein the first delay circuit includes a first RC circuit, a dc reference, and a second comparator having a first input driven by the first RC circuit and a second input driven by the dc reference wherein the first time delay is determined by the point at which a voltage level of an output of the RC circuit exceeds a voltage level of an output of the dc reference.

7. The circuit arrangement of claim 6 wherein the dc voltage level generated by the dc reference is variable and varying the dc voltage generated by the dc reference varies the first time delay caused by the first delay circuit.

8. The circuit arrangement of claim 6 wherein a rise time of a signal generated by the RC circuit is variable and varying the rise time of a signal generated by the RC circuit varies the first time delay caused by the first delay circuit.

9. The circuit arrangement of claim 6 wherein the second delay circuit is a substantial duplicate of the first delay circuit.

10. The circuit arrangement of claim 1 wherein the recombination circuit includes:
a logical OR gate having a first input driven by the first delay circuit; and
a second input driven by the second delay circuit such that rising edge timing of an output signal of the logical OR gate is alternately determined by the output of the first delay circuit and the output of the second delay circuit.

11. The circuit arrangement of claim 10 wherein the recombination circuit includes a flip-flop driven by the logical OR gate output signal, the flip-flop generating a flip-flop output signal having a rising edge delay determined by a first set of alternate rising edges of the logical OR gate output signal and a falling edge delay determined by a second set of alternate rising edges of the logical OR gate output signal.

12. A method of generating a signal having a delayed rising edge and a delayed falling edge with respect to an input signal including:
inverting the input signal to create an inverted signal delaying a rising edge of the input signal by driving a first delay circuit with the input signal;
delaying a rising edge of the inverted signal by driving a second delay circuit with the inverted signal; and
combining an output of the first delay circuit and an output of the second delay circuit to generate a composite signal representing the input signal with both the rising edge and the falling edge delayed.

13. The method of claim 12 wherein the input signal is a digital waveform.

14. The method of claim 12 wherein the step of combining an output of the first delay circuit and an output of the second delay circuit includes generating a composite signal having a first variable delay in a rising edge thereof and a second variable delay in a falling edge thereof.

15. The method of claim 14 wherein the first variable delay is equal to the second variable delay.

16. The method of claim 14 wherein the first variable delay is not equal to the second variable delay.

17. The method of claim 12 wherein the step of delaying the rising edges of the input signal includes:
generating an intermediate signal from the input signal, the intermediate signal having a ramping portion;
comparing the level of the ramping portion of the intermediate signal with a predetermined de reference level; and
generating a digital waveform rising edge on an output signal when the level of the ramping portion of the intermediate signal exceeds the predetermined dc reference level.

18. The method of claim 17 wherein the step of generating an intermediate signal includes generating an intermediate signal having a variable non-linear rising edge.

19. The method of claim 12 wherein the step of combining an output of the first delay circuit and an output of the second delay circuit includes:
generating an intermediate signal having a rising edge delay alternately determined by the rising edge delay of the input signal and the rising edge delay of the inverted signal; and
generating the composite output signal having rising edge timing determined by a first set of alternate rising edges of the intermediate signal and falling edge timing determined by a second set of alternate rising edges of the intermediate signal.
